(19) United States
(12) Patent Application Publication
(10) Pub. No.: US 2006/0205248 A1
(43) Pub. Date: Sep. 14, 2006

(54) Voltmeter relay with shaped base which contains slots designed to form seatings for the insertion of "faston" connectors

(75) Inventor: Pietro Cecconi, Monza (IT)

Correspondence Address: YOUNG & THOMPSON, 745 SOUTH 23RD STREET, 2ND FLOOR, ARLINGTON, VA, 22202, US

(73) Assignee: ELECTRICA S.R.L., MILANO (IT)

(21) Appl. No.: 11/359,448

(22) Filed: Feb. 23, 2006

(30) Foreign Application Priority Data
Mar. 10, 2005 (IT) PC 2005 U 000006

(51) Int. Cl. H05K 1/00

(52) U.S. Cl. 439/76.2

(57) ABSTRACT

A voltage sensitive relay of the type including a support base (1) on which are mounted the devices constituting the relay, including a coil (3), movable contacts, return springs, and a set of terminals (4, 5, 6, 7) that project from the opposite side of the base to allow the insertion of faston connectors (8), characterized in that the base is shaped to form split levels, wherein the level of the areas in which the terminals are fitted retracts into the lid in relation to the remaining part, so as to form seatings deep enough to allow overtravel of the fastons inserted onto the terminals, while the level near the devices that develop heat is located further away from the upper wall of the lid, so as to leave more inner space for air circulation around the devices.

The present innovation relates to a voltage sensitive relay, or voltmeter relay, designed in particular for application to refrigerator compressor motors, said relay being characterised by the particular configuration of the base, which is shaped in such a way as to form split levels in the areas containing the terminals for the faston connectors and in the remainder of the base, so as to provide more ventilation space around components liable to generate heat, such as the coil, and at the same time provide terminal seatings which are deep enough to allow overtravel of the faston connectors when they are inserted, to ensure that they are coupled to the terminals.

The result is a voltage sensitive relay which is more useful than those currently known, but whose overall size is no larger than known types due to the particular shape of the base.

In refrigerators, the motor/compressor assembly is generally made in a single hermetically sealed block, contained in a metal casing fitted with connectors suitable for connection to the power cables and to the motor starting and protection devices.

Said connectors are a standardised type and generally comprise three male contacts, to which a starting or starting and protection device is fitted, which said device comprises means able to provide for a short time the pick-up current required to start the motor, and heat-activated protection devices.

Many starter devices are constituted by a relay, the contacts of which are closed for as long as necessary to supply the pick-up current to the motor windings; said relay opens when the motor reaches the required number of revolutions, thus cutting off said pick-up current, so that the motor only receives the current required to power it.

The innovation relates to a starter device of this type.

The problem solved by the innovation is to make a voltmeter relay whose size does not exceed that of known relays, but which contains more space than current relays for insertion of the faston connectors through which current is supplied to the motor, and in particular faston connectors surrounded by a plastic insulating sheath, which increases their size.

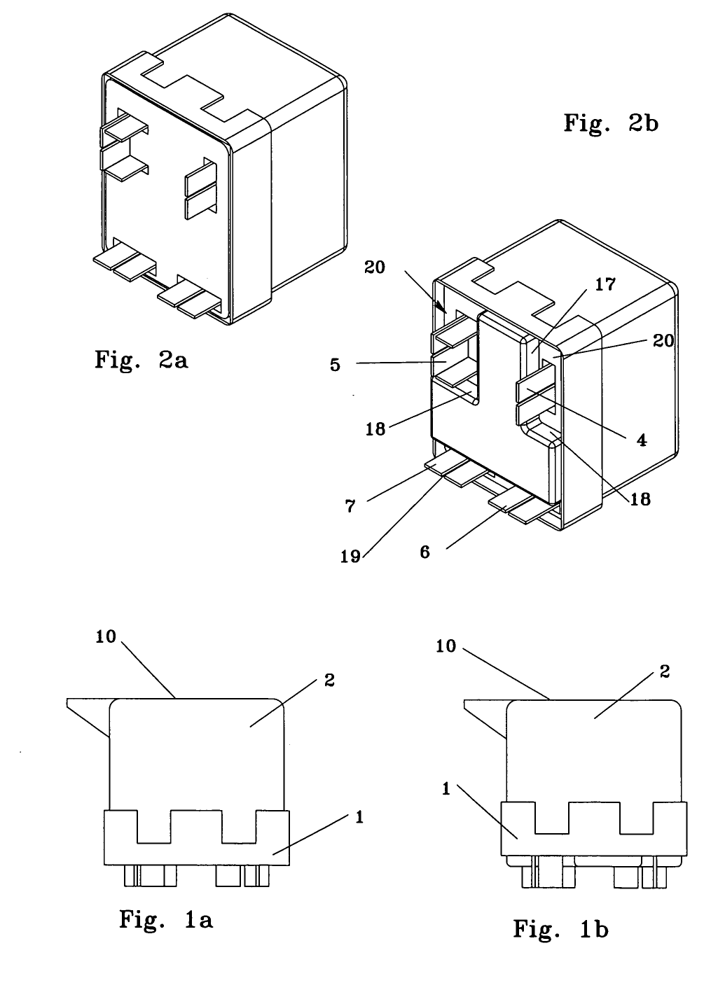

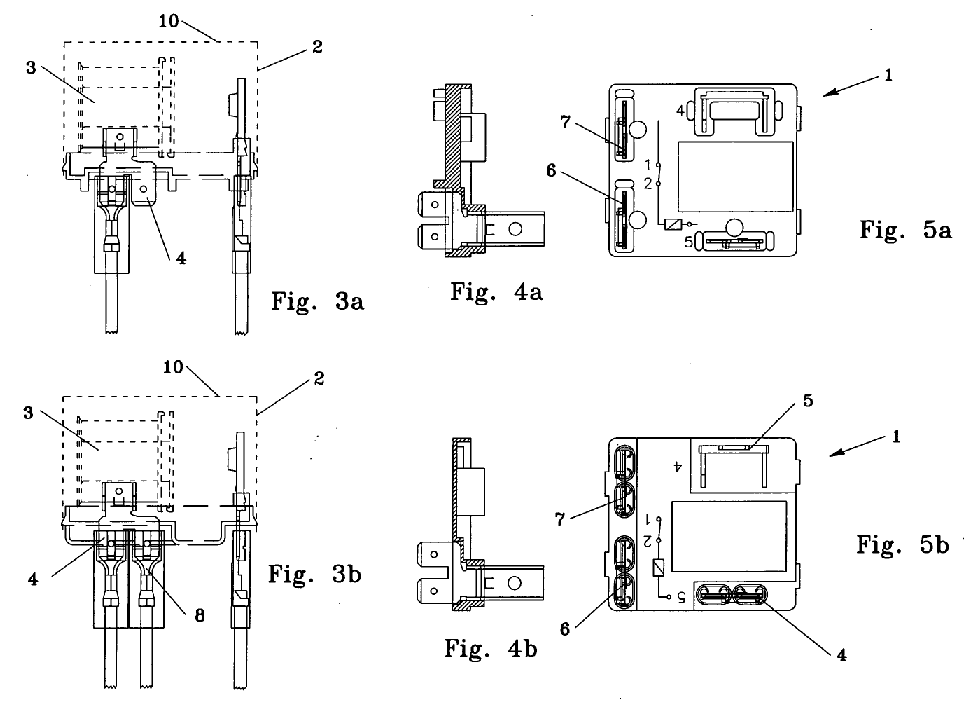

This innovation will now be described in detail, by way of example but not of limitation, by reference to the annexed figures wherein:
FIGS. 1A and 1B respectively are side views of a relay of known type and a relay according to the invention, with the casing closed;
FIGS. 2A and 2B show the base of the relay illustrated in the preceding figures, seen from below;
FIGS. 3A and 3B show cross-sections of the base of a known relay and a relay according to the invention respectively, with some of the internal components indicated with a broken line, and faston connectors connected to the terminals on the base;
FIGS. 4A and 4B are cross-sections of the bases shown in FIGS. 3A and 3B, according to a plane orthogonal to the preceding one;
FIGS. 5A and 5B are plan views, shown from below, of the bases of a known relay and a relay according to the invention respectively.

In the figures illustrating the known relay and the relay according to the invention, the same components are indicated with the same numbers.

In the annexed figures, a voltage sensitive relay according to the invention comprises a base 1, on which are mounted the various components constituting the relay, said base being closed by a snap-on lid 2 secured in a known way by teeth or the like.

A number of components are mounted on the base, including a relay coil 3 which activates a series of contacts not illustrated as they are of known type.

On base 1 are also mounted a pair of terminals or connectors 4 and 5, through which passes the electrical current that supplies coil 3, and a further pair of terminals 6 and 7 connected to the opening contact of the relay. Said terminals, which project from the bottom of base 1, connect a series of faston connectors shown as 8 in the figures, which are generally equipped with an elastic tooth that is inserted into a hole in the corresponding terminal to prevent the connector from becoming accidentally detached.

To ensure that the tooth correctly engages the hole, when the faston is inserted onto the terminal it must be pushed a little further in so that the tooth slightly overshoots the edge of the hole. 1 or 2 mm overtravel is therefore necessary.

It would obviously be possible to make longer terminals, but this would require an increase in the overall size of the device, which it is preferable to avoid because these relays must be as small as possible.

However, it is necessary to leave some space between the base and the components that generate heat during operation, such as coil 3, to ensure sufficient ventilation. This constitutes a problem in known relays, which have a flat base, because if the base is maintained at a certain distance from the inner components, as the overall size of the device cannot be increased the terminals cannot be designed to project from the base by more than a certain measurement.

Said problem is now solved by the present innovation, in accordance with which base 1 is shaped to form two parallel split levels, one of which (the level near the terminal connectors) is in a raised position (ie. closer to the upper edge of the lid), while the other (the level near the areas in which the coil and the other devices that may generate heat are located) is in a lowered position (ie. further away from upper wall 10 of the lid).

A series of cavities or seatings 20 are consequently formed in the base, from which terminals 4, 5, 6 and 7 project.

In the case of double terminals, the slot that separates the two terminals, shown as 19, is large enough to allow a pair of fastons, each with an insulating sheath, to be inserted onto the terminals. Moreover, in accordance with an advantageous characteristic of the innovation, the walls that connect the two split levels of the base, shown as 18, which act as guides during insertion of the fastons, can be slightly slanted or bevelled to form a guide that facilitates the insertion of the faston connectors onto the terminals, for example when the relay is located in a position where it is not easily visible.

As will clearly appear from the description provided, although the voltage sensitive relay according to the invention retains the same external dimensions as known relays, due to the particular configuration of its base the terminals can project further, allowing the faston overtravel required to ensure perfect coupling and providing more free space around the components that generate heat, in order to improve air circulation.

Moreover, in the relay according to the innovation, faston connectors with an insulating sheath can be inserted deep into the corresponding seating, so that the insulating sheath completely covers the metal parts, which ensures greater safety because even if the device is fitted close to metal walls, as often occurs, the risk that an arc or spark will be created between the connectors and the nearby wall is eliminated.

The dimensions and the materials employed can obviously vary, depending on use.

1- Voltage sensitive relay of the type comprising a support base on which are mounted the devices constituting the relay, including a coil, movable contacts, return springs, and a set of terminals that project from the opposite side of said base to allow the insertion of faston connectors, characterised in that said base is shaped to form split levels, wherein the level of the areas in which the terminals are fitted retracts into the lid in relation to the remaining part, so as to form seatings deep enough to allow overtravel of the fastons inserted onto said terminals, while the level near the devices that develop heat is located further away from the upper wall of the lid, so as to leave more inner space for air circulation around said devices.

2- Voltage sensitive relay as claimed in claim 1, wherein there is a space between the terminals and the walls connecting said split levels to allow the insertion of fastons with an insulating sheath.

3- Voltage sensitive relay as claimed in claim 2, wherein the walls connecting said split levels are bevelled to form a guide designed to facilitate the insertion of the fastons onto the terminals.
